(19) United States
(12) Patent Application Publication
(10) Pub. No.: US 2026/0003224 A1
(43) Pub. Date: Jan. 1, 2026

(54) DISPLAY MODULE AND DISPLAY DEVICE

(71) Applicant: Guangzhou China Star Optoelectronics Semiconductor Display Technology Co., LTd., Guangzhou (CN)

(72) Inventors: Feng LIU, Guangzhou (CN); Mingjong JOU, Guangzhou (CN); Junjie LI, Guangzhou (CN)

(73) Assignee: Guangzhou China Star Optoelectronics Semiconductor Display Technology Co., LTd., Guangzhou (CN)

(21) Appl. No.: 18/964,408

(22) Filed: Nov. 30, 2024

(30) Foreign Application Priority Data
Jul. 1, 2024 (CN) 202410874411.7
Jul. 3, 2024 (CN) 202410890569.3

(51) Int. Cl. G02F 1/1335; G02F 1/1339; H05K 1/18

(52) U.S. Cl. CPC G02F 1/133528; G02F 1/133512; G02F 1/1339; H05K 1/189; H05K 2201/10136

(57) ABSTRACT

A display module, where an opposing substrate is disposed on a light emitting side of the display module; a first polarizer is disposed on a side of the opposing substrate away from an array substrate and covers one or more connection pads; a second polarizer is disposed on a side of the array substrate away from the opposing substrate; a conductive light-shielding layer is provided on the first polarizer, the conductive light-shielding layer covers the connection pad(s) and a first bonding portion of one or more flexible printed circuits, and the conductive light-shielding layer is configured to be grounded.

### CROSS-REFERENCE TO RELATED APPLICATION

This disclosure claims priority to Chinese Patent Application No. 202410874411.7, filed with the China National Intellectual Property Administration (CNIPA) on Jul. 1, 2024, and Chinese Patent Application No. 202410890569.3, filed with the China National Intellectual Property Administration (CNIPA) on Jul. 3, 2024, the contents of which are incorporated herein by reference.

### TECHNICAL FIELD

The present disclosure relates to the field of display technology, and specifically to a display module and a display device.

### BACKGROUND

In an existing liquid crystal display panel with no bezel on four sides, a chip on film (COF) is placed on the back of this product in an inverted arrangement where the color film substrate and the array substrate are usually inverted, thereby achieving no bezel on the front side.

### SUMMARY

Embodiments of the present disclosure provide a display module and a display device.

Embodiments of the present disclosure provide a display module including a display area and a non-display area disposed on at least one side of the display area. The display module includes a liquid crystal display panel, a first polarizer, a second polarizer, and one or more flexible printed circuits.

The liquid crystal display panel includes an array substrate, an opposing substrate, and a sealant, the sealant is disposed between the array substrate and the opposing substrate and corresponds to a peripheral edge of the opposing substrate, the opposing substrate is disposed on a light emitting side of the display module, and the array substrate includes one or more connection pads disposed in the non-display area.

The first polarizer is disposed on a side of the opposing substrate away from the array substrate and covers the one or more connection pads.

The second polarizer is disposed on a side of the array substrate away from the opposing substrate.

The one or more flexible printed circuits each include a first bonding portion, the first bonding portion being bonded to at least one of the one or more connection pads.

A conductive light-shielding layer is provided on a side of the first polarizer closer to the array substrate, the conductive light-shielding layer is disposed in the non-display area, the conductive light-shielding layer covers the one or more connection pads and the first bonding portion of each flexible printed circuit, and the conductive light-shielding layer is configured to be grounded.

Accordingly, embodiments of the present disclosure also provide a display device including a display module as described in any of the above embodiments.

### BRIEF DESCRIPTION OF THE DRAWINGS

FIG. 1 is a schematic plan view of a display module in a first state provided by embodiments of the present disclosure.

FIG. 2 is a schematic plan view of a display module in a second state provided by embodiments of the present disclosure.

FIG. 3 is a schematic cross-sectional view cut along line AA of FIG. 2.

FIG. 4 is a schematic cross-sectional view cut along line BB of FIG. 2.

FIG. 5 is an enlarged view of region Y of FIG. 1.

FIG. 6 is a schematic diagram of an assembly process of a display module provided by embodiments of the present disclosure.

FIG. 7 is another schematic cross-sectional view cut along line AA of FIG. 2.

FIG. 8 is another schematic cross-sectional view cut along line BB of FIG. 2.

### DETAILED DESCRIPTION

Unless specified to the contrary, the used directional words such as “upper” and “lower” usually refer to the upper and lower sides of the device under the actual use or working state, specifically the directions shown in the drawings; the terms “inside” and “outside” are used in relation to the contour of the device; and the terms “first”, “second”, “third”, etc. are used only as indications, and are not intended to impose numerical requirements or establish an order.

In the course of researching and practicing the related art, the inventors of the present disclosure found that since the array substrate is located on the light emitting side and the array substrate has a high number of metal traces, the reflectivity of the display panel is relatively high, which affects the picture quality.

Considering the above situation, embodiments of the present disclosure provide a display module and a display device, which are described in detail below. It is to be noted that the order in which the following embodiments are described does not serve as a limitation for the preferred order of embodiments.

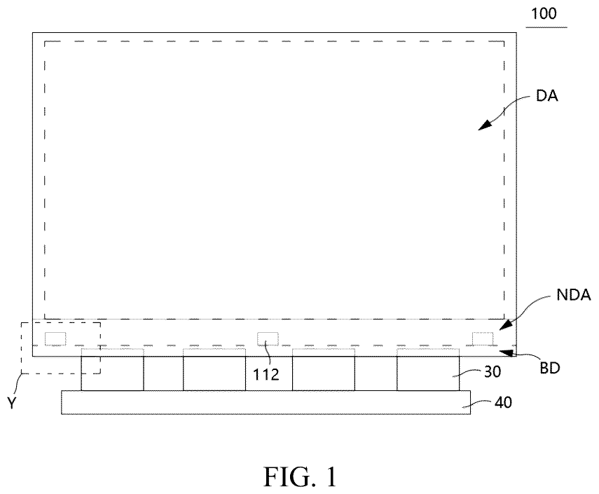

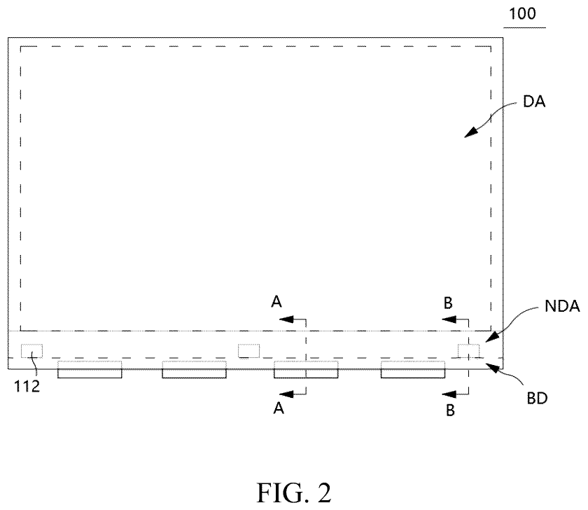

Referring to FIGS. 1 to 2, the display module 100 is a liquid crystal display module according to the embodiments. The display module 100 includes a liquid crystal display panel 10 configured with a polarizer, a flexible printed circuit 30, and a driver board 40. One end of the flexible printed circuit 30 is bonded to a bonding area BD of the liquid crystal display panel 10, and the other end of the flexible printed circuit 30 is bonded to the driver board 40.

FIG. 1 is a schematic plan view of the display module 100 when the flexible printed circuit 30 is in a flat state, and FIG. 2 is a schematic plan view of the display module 100 when the flexible printed circuit 30 is in a bent state.

In the display module 100 of the embodiments, the liquid crystal display panel 10 may be a liquid crystal panel based on a fringe-field switching (FFS) technology driving architecture, a liquid crystal panel based on an in-plane switching (IPS) technology driving architecture, a liquid crystal panel based on a vertical alignment (VA) technology driving architecture, and so on.

The flexible printed circuit 30 may be a chip on film or may be a flexible printed circuit that is not configured with any integrated circuit chip. Optionally, the number of flexible printed circuit(s) 30 may be one or more. It is to be understood that depending on the size of the liquid crystal display panel 10, the number of flexible printed circuit(s) 30 required will be adjusted accordingly; for example, when the size of the liquid crystal display panel 10 is small, a single flexible printed circuit 30 may be sufficient for bonding connection.

Optionally, the driver board 40 may be connected to multiple flexible printed circuits 30. The driver board 40 may be a printed circuit board configured with electronics, and the electronics may include a driver chip, a timing controller, a power management chip, and etc. The driver board 40 is configured to drive and control the liquid crystal display panel 10 to display a screen.

The display module 100 may include a display area DA and a non-display area NDA disposed on at least one side of the display area DA. The non-display area NDA includes the bonding area BD located in liquid crystal display panel 10.

The display area DA may be an area including pixels for displaying images. The pixels may be arranged in a matrix form. The pixels may have a rectangular shape, a diamond shape or a square shape in the plan view, but the embodiments are not limited thereto. For example, in the plan view, the pixels may have another quadrilateral shape other than the rectangular shape, the diamond shape and the square shape, another polygonal shape other than the quadrilateral shape, a circular shape or an elliptical shape.

The non-display area NDA may be an area that does not include any pixel and therefore does not display any image. The non-display area NDA may be arranged near (or peripheral to) the display area DA. In FIGS. 1 and 2, the non-display area NDA may surround the display area DA, but the embodiments are not limited thereto. The display area DA may be surrounded (e.g., partially surrounded) by the non-display area NDA.

The bonding area BD is provided within the non-display area NDA. The bonding area BD is provided on an array substrate 11, and the bonding area BD is an area used for being bonded to or connected to the flexible printed circuit 30. As shown in FIGS. 1 and 2, the bonding area BD is disposed on one side of the display area DA, but the embodiments are not limited thereto; for example, the bonding area BD may be disposed on two sides or three sides of the display area DA.

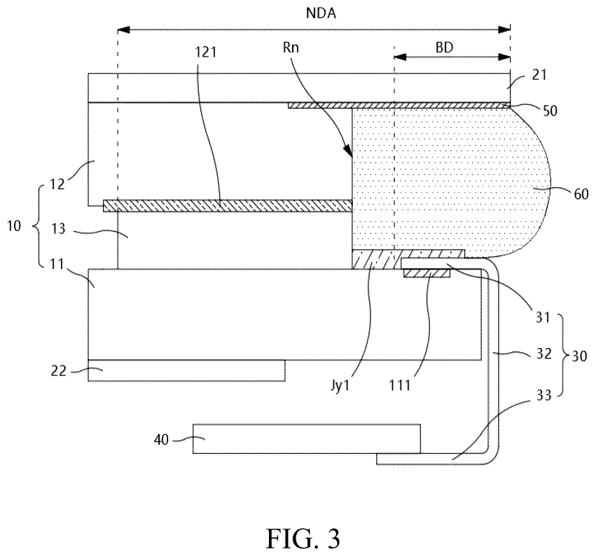

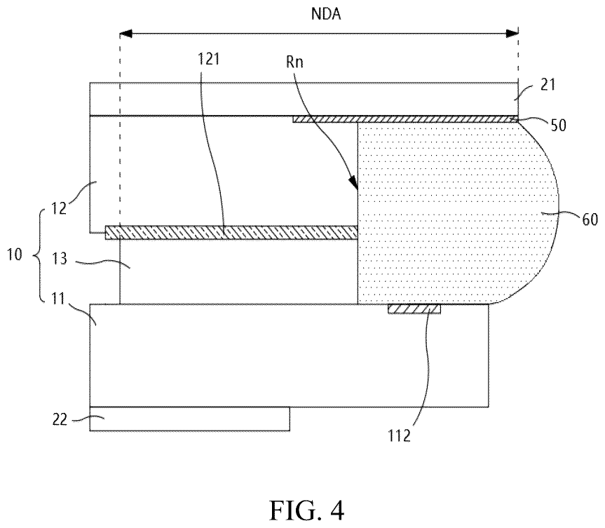

Referring to FIGS. 3 to 5, the liquid crystal display panel 10 includes the array substrate 11, an opposing substrate 12, and a sealant 13, and the sealant 13 is disposed between the array substrate 11 and the opposing substrate 12 and corresponds to a peripheral edge of the opposing substrate 12. The opposing substrate 12 is disposed on a light emitting side of the display module 100. The array substrate 11 includes connection pads 111 disposed in the non-display area NDA.

The polarizer includes a first polarizer 21 and a second polarizer 22. The first polarizer 21 is disposed on a side of the opposing substrate 12 away from the array substrate 11 and also covers the connection pads 111. The second polarizer 22 is disposed on a side of the array substrate 11 away from the opposing substrate 12. The flexible printed circuit 30 includes a first bonding portion 31, and the first bonding portion 31 is bonded to the connection pad 111.

A conductive light-shielding layer 50 is provided on a side of the first polarizer 21 closer to the array substrate 11, and the conductive light-shielding layer 50 is provided in the non-display area NDA. The conductive light-shielding layer 50 covers the connection pads 111 and the first bonding portion 31. The conductive light-shielding layer 50 is configured to be grounded.

In the embodiments of the present disclosure, the liquid crystal display panel 10 of the display module 100 is provided in a normal arrangement where the opposing substrate 12 is disposed on the light emitting side of the array substrate 11, thereby reducing the reflectivity of the entire surface of the display module 100. Furthermore, the first polarizer 21 fully covers the array substrate 11 to achieve no bezel on all four sides. And based on this, the conductive light-shielding layer 50 is provided under the first polarizer 21 and the conductive light-shielding layer 50 is grounded, thereby shielding the bonding area BD while improving the anti-static performance of the display module 100.

Optionally, in the liquid crystal display panel 10, a color film layer may be formed on the opposing substrate 12 or may be formed on the array substrate 11.

Optionally, in some embodiments of the present disclosure, the opposing substrate 12 further includes a black matrix layer 121, the black matrix layer 121 masking the sealant 13. In the non-display area NDA, the black matrix layer 121 partially overlaps the conductive light-shielding layer 50 in the thickness direction of the display module 100.

The black matrix layer 121 partially overlaps the conductive light-shielding layer 50, which causes the non-display area NDA of the liquid crystal display panel 10 to have a continuous black appearance, thereby improving the appearance and reducing the risk of light leakage from the sides.

Optionally, in some embodiments of the present disclosure, the conductive light-shielding layer 50 includes a black ink and second conductive particles disposed within the black ink, but the embodiments are not limited thereto. For example, the conductive light-shielding layer 50 may also be a black resin mixed with conductive particles or may be a black metal layer. Alternatively, the conductive light-shielding layer 50 may be a light-shielding body having other conductive materials.

Optionally, in some embodiments of the present disclosure, the array substrate 11 further includes a grounding electrode 112 disposed in the non-display area NDA, the grounding electrode 112 being disposed on the outside of the connection pad 111. The display module 100 further includes a conductive connector 60, the conductive connector 60 connecting the conductive light-shielding layer 50 to the grounding electrode 112.

The grounding electrode 112 can lead the static electricity of the array substrate 11 outwardly. Furthermore, the conductive connector 60 is used to connect the grounding electrode 112 to the conductive light-shielding layer 50 so that the conductive light-shielding layer 50 and the grounding electrode 112 share the electrostatic lead-out path to achieve a space-saving effect.

As shown in FIGS. 1 and 2, the number of grounding electrodes 112 may be more than one, and the grounding electrodes 112 are disposed to avoid the flexible printed circuit 30. The multiple grounding electrodes 112 are provided, thereby increasing the number of electrostatic lead-out paths, and improving the stability and reliability of electrostatic discharge.

Optionally, in some embodiments of the present disclosure, a receiving space Rn is formed by a side of the conductive light-shielding layer 50 closer to the array substrate 11, a side of the opposing substrate 12, a side of the sealant 13, and a side of the array substrate 11 closer to the conductive light-shielding layer 50.

The display module 100 further includes an insulating layer Jy1, the insulating layer Jy1 being provided within the receiving space Rn. The insulating layer Jy1 is disposed on the first bonding portion 31 and covers an outer periphery of the first bonding portion 31. The conductive connector 60 is filled in the receiving space Rn.

It is to be understood that the conductive connector 60 fills the receiving space Rn, and thus the conductive connector 60 not only encapsulates a side of the liquid crystal display panel 10, but also improves the waterproof and oxygen-proof performance of the liquid crystal display panel 10. The conductive connector 60 can support the first polarizer 21, thereby improving the flatness of the first polarizer 21.

In addition, the insulating layer Jy1 is disposed on the first bonding portion 31 and covers the outer periphery of the first bonding portion 31, thereby isolating the conductive connector 60 from the flexible printed circuit 30, and avoiding the conductive connector 60 from contacting the conductive pads and the traces of the flexible printed circuit 30, which can result in signal confusion or failure.

Optionally, in some embodiments of the present disclosure, the conductive connector 60 fills the entire receiving space Rn to allow the conductive connector 60 to maximally support the first polarizer 21 and encapsulate the side of the liquid crystal display panel 10.

In addition, since the conductive connector 60 is grounded, the conductive connector 60 fills the entire receiving space Rn, thereby increasing the contact area of the conductive connector 60, and thus improving the anti-static properties of the display module 100.

Optionally, in some embodiments of the present disclosure, the conductive connector 60 is connected to the side of the opposing substrate 12, the side of the sealant 13, the insulating layer Jy1, and the array substrate 11, and a side of the conductive connector 60 away from the sealant 13 protrudes from a side of the first polarizer 21 and a side of the array substrate 11.

It is to be understood that the conductive connector 60 protrudes from the side of the first polarizer 21 and the side of the array substrate 11, thereby ensuring that the conductive connector 60 can fully support the first polarizer 21, protect the side of the first polarizer 21 and the side of the array substrate 11 better and reduce the risk of the side of the first polarizer 21 and the side of the array substrate 11 being struck or scratched.

Optionally, in some embodiments of the present disclosure, the conductive connector 60 is black. The black conductive connector 60 can further mask the bonding area BD, thereby reducing metal reflectivity and improving the appearance.

Optionally, in some embodiments of the present disclosure, the conductive connector 60 includes a black resin and first conductive particles disposed within the black resin.

The conductive particles may include at least one of metal particles or graphene particles. Optionally, the metal particles may be silver particles, gold particles, or other metal particles.

The metal particles have a particle size between 2 μm and 6 μm, for example, it may be 2 μm, 3 μm, 4 μm, 5 μm or 6 μm. The graphene particles have a thickness of 1 nm, and the graphene particles have a length between 3 μm and 500 μm, for example, the length of the graphene particles may be 3 μm, 5 μm, 10 μm, 20 μm, 50 μm, 100 μm, 200 μm, 300 μm, 400 μm, or 500 μm.

Optionally, in some embodiments of the present disclosure, the flexible printed circuit 30 further includes an intermediate portion 32 and a second bonding portion 33, the intermediate portion 32 being connected between the first bonding portion 31 and the second bonding portion 33. The intermediate portion 32 is disposed along the side of the array substrate 11, and the second bonding portion 33 is disposed on the side of the array substrate 11 away from the opposing substrate 12. The conductive connector 60 masks the intermediate portion 32.

The conductive connector 60 masks the intermediate portion 32 of the flexible printed circuit 30, thereby facilitating better realization of the four sides without bezel.

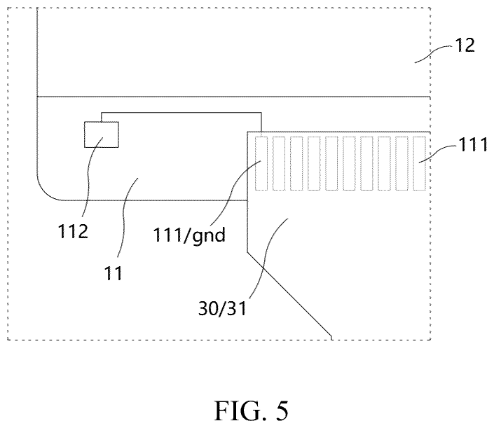

Optionally, referring to FIG. 5, in some embodiments of the present disclosure, the display module 100 further includes the driver board 40 connected to the second bonding portion 33, the driver board 40 being provided on the side of the array substrate 11 away from the opposing substrate 12. The connection pad 111 includes a grounding pad gnd, the grounding electrode 112 is electrically connected to the grounding pad gnd, and the grounding pad gnd is connected to the driver board 40 via the flexible printed circuit 30.

In the embodiments of the present disclosure, the display module 100 transfers the static electricity of the liquid crystal display panel 10 to the driver board 40 through the flexible printed circuit 30 and leads it out, thereby avoiding the setting up of any additional lead-out path and simplifying the structure.

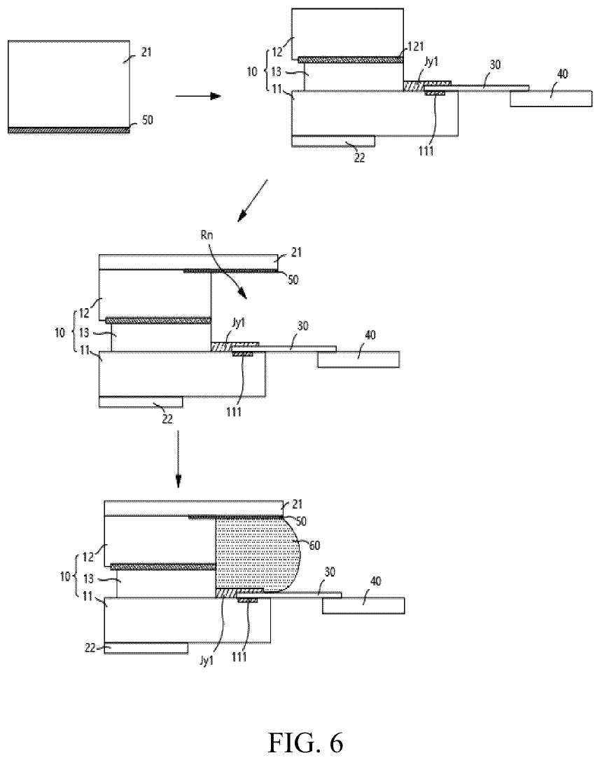

Referring to FIG. 6, in some embodiments of the present disclosure, the assembly process of the display module 100 is as follows. First, the conductive light-shielding layer 50 is formed on the side of the first polarizer 21. Thereafter, the flexible printed circuit 30 and the driver board 40 are bonded to the bonding area BD of the liquid crystal display panel 10 configured with the second polarizer 22. Then, the insulating layer Jy1 is formed on the bonding area to cover the first bonding portion 31 of the flexible printed circuit 30. Next, the first polarizer 21 is attached to the opposing substrate 12 of the liquid crystal display panel 10, the first polarizer 21 completely covering the array substrate 11, and the conductive light-shielding layer 50 covering the entire bonding area BD. Then, the conductive connector 60 is formed in the receiving space Rn using a spray of a resin material mixed with conductive particles.

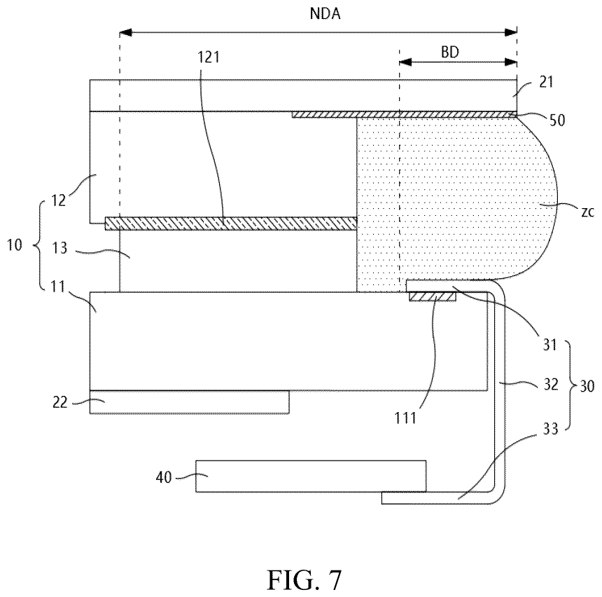

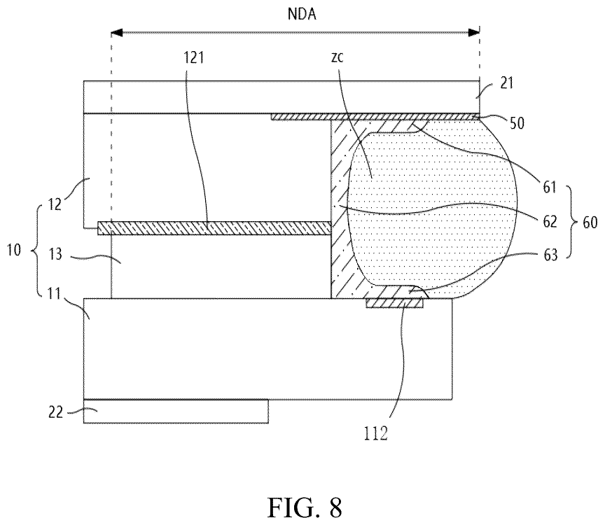

Referring to FIGS. 7 and 8, FIG. 7 illustrates a display module 100 according to one or more embodiments of the present disclosure and is a schematic cross-sectional view cut along line AA of FIG. 2, and FIG. 8 illustrates a display module 100 according to one or more embodiments of the present disclosure and is a schematic cross-sectional view cut along line BB of FIG. 2.

In FIGS. 7 and 8, different portions from the above embodiments will be described to avoid redundancy.

Referring to FIGS. 1, 7, and 8, the receiving space Rn is formed by the side of the conductive light-shielding layer 50 closer to the array substrate 11, the side of the opposing substrate 12, the side of the sealant 13, and the side of the array substrate 11 closer to the conductive light-shielding layer 50.

The conductive connector 60 is provided in the receiving space Rn, and in a plan view of the display module 100, the conductive connector 60 is disposed on the outside of the first bonding portion 31.

The conductive connector 60 includes a first connection portion 61, a second connection portion 62, and a third connection portion 63 sequentially connected. The first connection portion 61 is connected to the side of the conductive light-shielding layer 50 closer to the array substrate 11, the second connection portion 62 is connected to the side of the opposing substrate 12 and the side of the sealant 13, and the third connection portion 63 is connected to the grounding electrode 112.

In some embodiments, conductive connectors 60 are in one-to-one correspondence with grounding electrodes 112, and one grounding electrode 112 corresponds to one conductive connector 60. All the conductive connectors 60 are connected to the conductive light-shielding layer 50. Since the conductive connectors 60 are in one-to-one correspondence with the grounding electrodes 112, the conductive connectors 60 can be prevented from being connected to other electronic devices, and thus the insulating layer Jy1 is saved.

Optionally, in some embodiments of the present disclosure, the display module 100 further includes a support body zc, the support body zc filling in the receiving space Rn. The support body zc is connected to the side of the conductive light-shielding layer 50 closer to the array substrate 11, the side of the opposing substrate 12, the side of the sealant 13, and the side of the array substrate 11 closer to the conductive light-shielding layer 50.

The widths of the first connection portion 61 and the third connection portion 63 are each greater than the width of the second connection portion 62, and the support body ze is further filled between the first connection portion 61 and the third connection portion 63.

It is to be understood that the support body ze fills the receiving space Rn, and thus the support body zc not only encapsulates the side of the liquid crystal display panel 10, but also improves the waterproof and oxygen-proof performance of the liquid crystal display panel 10. The support body zc can support the first polarizer 21, thereby improving the flatness of the first polarizer 21.

In addition, the support body ze is further filled between the first connection portion 61 and the third connection portion 63, thereby encapsulating the conductive connector 60 and reducing the risk of corrosion of the conductive connector 60 by water and oxygen.

Optionally, the material of the support body ze may be an insulating resin or an inorganic material.

Optionally, in some embodiments of the present disclosure, the support body ze fills the entire receiving space Rn to allow the conductive connector 60 to maximally support the first polarizer 21 and encapsulate the side of the liquid crystal display panel 10.

Optionally, in some embodiments of the present disclosure, a side of the support body zc away from the sealant 13 protrudes from the side of the first polarizer 21 and the side of the array substrate 11.

It is to be understood that the support body ze protrudes from the side of the first polarizer 21 and the side of the array substrate 11, thereby ensuring that the support body zc can fully support the first polarizer 21, protect the side of the first polarizer 21 and the side of the array substrate 11 better, and reduce the risk of the side of the first polarizer 21 and the side of the array substrate 11 being struck or scratched.

Optionally, in some embodiments of the present disclosure, the support body ze is black. The black support body zc can further mask the bonding area BD, thereby reducing metal reflectivity and improving the appearance.

Optionally, in some embodiments of the present disclosure, the flexible printed circuit 30 further includes an intermediate portion 32 and a second bonding portion 33, the intermediate portion 32 being connected between the first bonding portion 31 and the second bonding portion 33. The intermediate portion 32 is disposed along the side of the array substrate 11, and the second bonding portion 33 is disposed on the side of the array substrate 11 away from the opposing substrate 12. The support body zc masks the intermediate portion 32, thereby facilitating better realization of the four sides without bezel.

Accordingly, embodiments of the present disclosure also provide a display device including the display module 100 as described in any of the above embodiments.

It is to be understood that the structure of the display module of the display device of the embodiment of the present disclosure is similar or the same as the structure of the display module 100 of any of the above embodiments, and thus will not be repeated herein.

Optionally, the display device may be a variety of products and may be used within the respective products, the variety of products including, for example, televisions, laptop computers, monitors, billboards, internet of things (IoT) devices, and portable electronic devices including mobile telephones, smart telephones, tablet personal computers, mobile communication terminals, electronic organizers, e-books, portable media players (PMPs), navigation equipment, and ultra-mobile personal computers (UMPCs).

Furthermore, the display device according to some embodiments may be applied to and may be used within a wearable device, the wearable device including a smartwatch, a watch phone, a display of the glasses type and a head-mounted display (HMD). Furthermore, according to some embodiments, the display device may be applied to an instrument panel for an automobile, to a display in a central dashboard of an automobile or in a central information display (CID) arranged on the dashboard, to an interior mirror display serving as a side mirror of an automobile, and to a display of an entertainment system arranged on the backside of a front seat for a rear seat passenger in an automobile.

In the embodiments of the present disclosure, the liquid crystal display panel of the display device is provided in the normal arrangement where the opposing substrate is disposed on the light emitting side of the array substrate, thereby reducing the reflectivity of the entire surface of the display module. Furthermore, the first polarizer fully covers the array substrate to achieve no bezel on all four sides, and based on this, the conductive light-shielding layer is provided under the first polarizer and the conductive light-shielding layer is grounded, thereby shielding the bonding area while improving the anti-static performance of the display module.

What is claimed is:

1. A display module, comprising a display area and a non-display area disposed on at least one side of the display area, and the display module comprising:
a liquid crystal display panel comprising an array substrate, an opposing substrate, and a sealant, the sealant being disposed between the array substrate and the opposing substrate and corresponding to a peripheral edge of the opposing substrate, the opposing substrate being disposed on a light emitting side of the display module, and the array substrate comprising one or more connection pads disposed in the non-display area;
a first polarizer disposed on a side of the opposing substrate away from the array substrate and covering the one or more connection pads;
a second polarizer disposed on a side of the array substrate away from the opposing substrate; and
one or more flexible printed circuits each comprising a first bonding portion, the first bonding portion being bonded to at least one of the one or more connection pads;
wherein a conductive light-shielding layer is provided on a side of the first polarizer closer to the array substrate, the conductive light-shielding layer is disposed in the non-display area, the conductive light-shielding layer covers the one or more connection pads and the first bonding portion of each flexible printed circuit, and the conductive light-shielding layer is configured to be grounded.

2. The display module according to claim 1, wherein the array substrate further comprises one or more grounding electrodes disposed in the non-display area, each grounding electrode being disposed on an outside of the one or more connection pads; and
wherein the display module further comprises one or more conductive connectors, each conductive connector connected to the conductive light-shielding layer and to a corresponding one of the one or more grounding electrodes.

3. The display module according to claim 2, wherein a receiving space is formed by a side of the conductive light-shielding layer closer to the array substrate, a side of the opposing substrate, a side of the sealant, and a side of the array substrate closer to the conductive light-shielding layer;
the display module further comprises an insulating layer, the insulating layer being disposed in the receiving space on the first bonding portion of each flexible printed circuit and covering an outer periphery of the first bonding portion; and
the one or more conductive connectors are filled in the receiving space.

4. The display module according to claim 3, wherein the one or more conductive connectors fill the entire receiving space.

5. The display module according to claim 3, wherein the one or more conductive connectors are each connected to the side of the opposing substrate, the side of the sealant, the insulating layer, and the array substrate, and a side of each conductive connector away from the sealant protrudes from a side of the first polarizer and a side of the array substrate.

6. The display module according to claim 5, wherein the one or more conductive connectors are black.

7. The display module according to claim 6, wherein each flexible printed circuit further comprises an intermediate portion and a second bonding portion, the intermediate portion being connected between the first bonding portion and the second bonding portion;
the intermediate portion is disposed along the side of the array substrate, and the second bonding portion is disposed on the side of the array substrate away from the opposing substrate; and
the intermediate portion is masked by a corresponding one of the one or more conductive connectors.

8. The display module according to claim 7, wherein the display module further comprises a driver board connected to the second bonding portion of each flexible printed circuit, the driver board being provided on the side of the array substrate away from the opposing substrate; and
the one or more connection pads comprise one or more grounding pads, each of the one or more grounding electrodes is electrically connected to a corresponding one of the one or more grounding pads, and the one or more grounding pads are each connected to the driver board via a corresponding one of the one or more flexible printed circuits.

9. The display module according to claim 2, wherein the one or more conductive connectors each comprise a black resin and first conductive particles disposed within the black resin.

10. The display module according to claim 2, wherein a receiving space is formed by a side of the conductive light-shielding layer closer to the array substrate, a side of the opposing substrate, a side of the sealant, and a side of the array substrate closer to the conductive light-shielding layer;
the one or more conductive connectors are disposed in the receiving space, and in a plan view of the display module, the one or more conductive connectors each are disposed on an outside of the first bonding portion of a corresponding one of the one or more flexible printed circuits; and
the one or more conductive connectors each comprise a first connection portion, a second connection portion, and a third connection portion sequentially connected, the first connection portion is connected to the side of the conductive light-shielding layer closer to the array substrate, the second connection portion is connected to the side of the opposing substrate and the side of the sealant, and the third connection portion is connected to the corresponding grounding electrode.

11. The display module according to claim 10, wherein the display module further comprises a support body, the support body is filled in the receiving space, and the support body is connected to the side of the conductive light-shielding layer closer to the array substrate, the side of the opposing substrate, the side of the sealant, and the side of the array substrate closer to the conductive light-shielding layer; and
widths of the first connection portion and the third connection portion are each greater than a width of the second connection portion, and the support body is also filled between the first connection portion and the third connection portion.

12. The display module according to claim 11, wherein the support body fills the entire receiving space.

13. The display module according to claim 11, wherein a side of the support body away from the sealant protrudes from a side of the first polarizer and a side of the array substrate.

14. The display module according to claim 13, wherein the support body is black.

15. The display module according to claim 14, wherein each flexible printed circuit further comprises an intermediate portion and a second bonding portion, the intermediate portion being connected between the first bonding portion and the second bonding portion;
the intermediate portion is disposed along the side of the array substrate, and the second bonding portion is disposed on the side of the array substrate away from the opposing substrate; and
the support body masks the intermediate portion.

16. The display module according to claim 15, wherein the display module further comprises a driver board connected to the second bonding portion of each flexible printed circuit, the driver board being provided on the side of the array substrate away from the opposing substrate; and
the one or more connection pads comprise one or more grounding pads, each of the one or more grounding electrodes is electrically connected to a corresponding one of the one or more grounding pads, and the one or more grounding pads are each connected to the driver board via a corresponding one of the one or more flexible printed circuits.

17. The display module according to claim 1, wherein the opposing substrate comprises a black matrix layer, the black matrix layer masking the sealant; and
in a thickness direction of the display module, the black matrix layer partially overlaps the conductive light-shielding layer in the non-display area.

18. The display module according to claim 1, wherein the conductive light-shielding layer comprises a black ink and second conductive particles disposed within the black ink.

19. The display module according to claim 2, wherein the conductive light-shielding layer comprises a black ink and second conductive particles disposed within the black ink.

20. A display device, comprising a display module;
wherein the display module comprises a display area and a non-display area disposed on at least one side of the display area;
wherein the display module comprising:
a liquid crystal display panel comprising an array substrate, an opposing substrate, and a sealant, the sealant being disposed between the array substrate and the opposing substrate and corresponding to a peripheral edge of the opposing substrate, the opposing substrate being disposed on a light emitting side of the display module, and the array substrate comprising one or more connection pads disposed in the non-display area;
a first polarizer disposed on a side of the opposing substrate away from the array substrate and covering the one or more connection pads;
a second polarizer disposed on a side of the array substrate away from the opposing substrate; and
one or more flexible printed circuits each comprising a first bonding portion, the first bonding portion being bonded to at least one of the one or more connection pads;
wherein a conductive light-shielding layer is provided on a side of the first polarizer closer to the array substrate, the conductive light-shielding layer is disposed in the non-display area, the conductive light-shielding layer covers the one or more connection pads and the first bonding portion of each flexible printed circuit, and the conductive light-shielding layer is configured to be grounded.
